(19) United States
(12) Patent Application Publication
(10) Pub. No.: US 2025/0055176 A1
(43) Pub. Date: Feb. 13, 2025

(54) ELECTRONIC COMPONENT MODULE AND WIRELESS COMMUNICATION DEVICE COMPRISING SAME

(71) Applicant: Murata Manufacturing Co., Ltd., Nagaokakyo-shi (JP)

(72) Inventors: Yoshinori YAMAWAKI, Nagaokakyo-shi (JP); Noboru KATO, Nagaokakyo-shi (JP); Ryosuke WASHIDA, Nagaokakyo-shi (JP); Yoichi SAITO, Nagaokakyo-shi (JP); Masaki KASAI, Nagaokakyo-shi (JP)

(21) Appl. No.: 18/930,062

(22) Filed: Oct. 29, 2024

Related U.S. Application Data
(63) Continuation of application No. PCT/JP2023/019147, filed on May 23, 2023.

(30) Foreign Application Priority Data
May 24, 2022 (JP) 2022-084601
Jul. 25, 2022 (JP) 2022-118120

(51) Int. Cl. H01Q 1/22; H01Q 1/02; H01Q 9/06

(52) U.S. Cl. CPC H01Q 1/2283; H01Q 1/02; H01Q 9/065

(57) ABSTRACT

An electronic component module includes a first substrate, a coupling electrode and a second substrate. The coupling electrode is provided on a first surface of the first substrate, the coupling electrode is configured to be electromagnetically coupled with a conductor pattern on an antenna member. The second substrate is provided on the first surface of the first substrate, the second substrate covers the coupling electrode. A first thermal resistance between the coupling electrode and the second substrate is smaller than a second thermal resistance between the coupling electrode and the first substrate.

### CROSS REFERENCE TO RELATED APPLICATIONS

This application is a continuation of International Application No. PCT/JP2023/019147, filed May 23, 2023, which claims priority to Japanese Patent Application No. 2022-084601, filed May 24, 2022, and Japanese Patent Application No. 2022-118120, filed Jul. 25, 2022, the entire contents of each of which are hereby incorporated by reference in their entireties.

### TECHNICAL FIELD

The present disclosure relates to an electronic component module and a wireless communication device including the same.

### BACKGROUND

In a related example of a method for manufacturing an RFID tag (also referred to as a wireless communication device), such as that disclosed in international patent application WO 2018/012391 A, in the RFID tag,: a base film (also referred to as a member) provided with an antenna pattern (also referred to as a conductor pattern) is conveyed toward a mounting position, and a radio-frequency integrated circuit (RFIC) element (an electronic component module) with a seal is stuck to the antenna pattern at the mounting position. The RFIC element with the seal, which is stuck to a tape, is picked up, and the picked RFIC element with the seal is stuck (fixed) to the antenna pattern.

### SUMMARY

However, in the case of the manufacturing method described in in international patent application WO 2018/012391 A, it is necessary to pick up the RFIC element with the seal while peeling off the RFIC element with the seal from the tape, and thus it takes time to pick up the RFIC element with the seal. In addition, there is a case where the peeling of the RIFC element fails.

It is noted that, in some examples, a method for sticking the electronic component module to the member (e.g., antenna member), can use a hot melt adhesive. Since the hot melt adhesive is in a cured state at timing other than the sticking timing, the hot melt adhesive is easier to handle than the seal. However, it is necessary to heat the hot melt adhesive and soften the entire hot melt adhesive at the time of sticking, and it takes time to soften the entire hot melt adhesive.

Therefore, according to an exemplary aspect, an object of the present disclosure is to stick an electronic component module to a member including a conductor pattern via a hot melt adhesive in a short time.

In order to solve the above problem, according to an exemplary aspect of the present disclosure, an electronic component module stuck to a member including a conductor pattern via a hot melt adhesive is provided. The electronic component includes a first substrate; a coupling electrode provided on a first surface of the first substrate and being electromagnetically coupled to the conductor pattern of the member; and a second substrate provided on the first surface of the first substrate and covering the coupling electrode. Further, a first thermal resistance between the coupling electrode and the second substrate is smaller than a second thermal resistance between the coupling electrode and the first substrate.

According to another exemplary aspect of the disclosure, an electronic component module includes a first substrate, a second substrate and a coupling electrode disposed between the first substrate and the second substrate. The second substrate is configured to be stuck to an antenna member via a hot melt adhesive, and cause the coupling electrode to be electromagnetically coupled with an antenna pattern of the antenna member. Further, a first thermal resistance between the coupling electrode and the second substrate is smaller than a second thermal resistance between the coupling electrode and the first substrate to facilitate a use of the hot melt adhesive to stick the electronic component module to the antenna member.

Also, according to another exemplary aspect of the present disclosure, a wireless communication device is provided that includes the above electronic component module; and an antenna member including an antenna pattern electromagnetically coupled to the coupling electrode of the electronic component module, the electronic component module stuck thereto via a hot melt adhesive.

According to the exemplary aspects of the present disclosure, the electronic component module can be stuck or adhered to the member including the conductor pattern via the hot melt adhesive in a short time.

### BRIEF DESCRIPTION OF THE DRAWINGS

FIG. 1 is a perspective view of a wireless communication device according to one exemplary embodiment of the present disclosure.

FIG. 2 is a top view of the wireless communication device.

FIG. 3 is an exploded perspective view of an RFIC module.

FIG. 4 is an exploded perspective view of an electronic component in the RFIC module.

FIG. 5 is an equivalent circuit diagram of the wireless communication device.

FIG. 6 is a cross-sectional view of a part of the wireless communication device including the RFIC module immediately before sticking.

FIG. 7 is an exploded perspective view of an RFIC module according to another exemplary embodiment of the present disclosure.

FIG. 8 is a top view of a wireless communication device according to a different exemplary embodiment of the present disclosure.

FIG. 9 is an exploded perspective view of an RFIC module in the wireless communication device according to the different exemplary embodiment.

FIG. 10 is an exploded perspective view of an electronic component in the RFIC module of the wireless communication device according to the different exemplary embodiment.

FIG. 11 is a top view of a wireless communication device according to one modification of the different exemplary embodiment.

FIG. 12 is a top view of a wireless communication device according to another modification of the different exemplary embodiment.

### DETAILED DESCRIPTION

Hereinafter, exemplary embodiments of the present disclosure will be described with reference to the drawings.

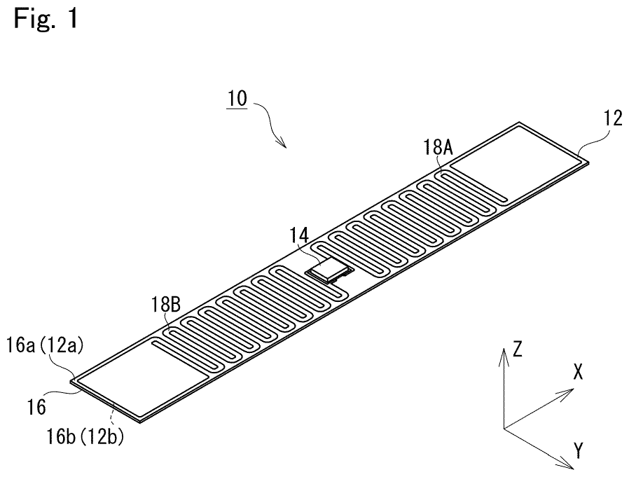

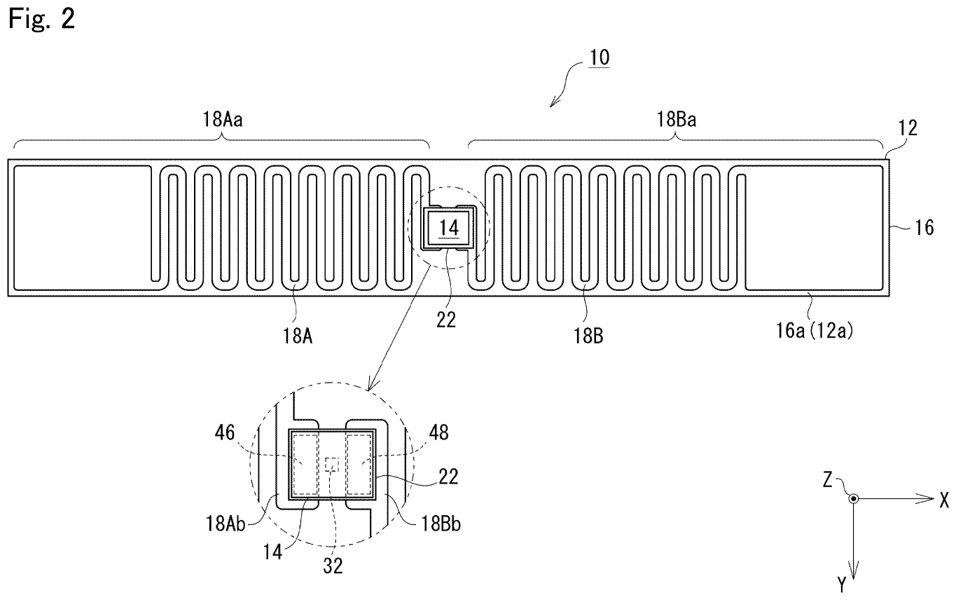

FIG. 1 is a perspective view of a wireless communication device according to one exemplary embodiment of the present disclosure, and FIG. 2 is a top view of the wireless communication device. For exemplary aspects, an X-Y-Z coordinate system in the drawings is provided for facilitating understanding of the present disclosure, and does not limit the present disclosure. In this regard, an X-axis direction indicates a longitudinal direction of the wireless communication device, a Y-axis direction indicates a width direction, and a Z-axis direction indicates a thickness direction.

As shown in FIGS. 1 and 2, a wireless communication device 10 has a strip shape and is configured as a so-called radio-frequency identification (RFID) tag.

Specifically, as shown in FIGS. 1 and 2, the wireless communication device 10 has an antenna member 12 and a radio-frequency integrated circuit (RFIC) module 14 provided in the antenna member 12.

The antenna member 12 of the wireless communication device 10 has a strip shape (an elongated rectangular shape) and includes an antenna substrate 16 and antenna patterns 18A, 18B provided on one surface 16a of the antenna substrate 16 (also referred to as a first main surface 12a of the antenna member 12).

The antenna substrate 16 is a flexible sheet-shaped member made of an insulating material such as a polyimide resin. As shown in FIGS. 1 and 2, the antenna substrate 16 also includes surfaces 16a, 16b that function as the first main surface 12a and a second main surface 12b of the antenna member 12. Since the antenna substrate 16, which is a main component of the antenna member 12, has flexibility, the antenna member 12 can also have flexibility.

The antenna patterns 18A, 18B are configured as antennas for the wireless communication device 10 to wirelessly communicate with an external communication apparatus (for example, when the wireless communication device 10 is configured as an RFID tag, a reader/writer apparatus). In the present exemplary embodiment, the antenna patterns 18A, 18B are conductor patterns made of metal foil of silver, copper, aluminum, or the like, for example.

In addition, the antenna patterns 18A, 18B include radiating portions 18Aa, 18Ba for transmitting and receiving radio waves and coupling portions 18Ab, 18Bb for electrically connecting to the RFIC module 14.

In the case of the present exemplary embodiment, the radiating portions 18Aa, 18Ba of the antenna patterns 18A, 18B are dipole antennas and have a meander shape. Further, the radiating portion 18Aa, 18Ba respectively extend from the coupling portions 18Ab, 18Bb provided at a central portion in a longitudinal direction (the X-axis direction) of the antenna substrate 16 toward both ends of the antenna substrate 16.

The coupling portions 18Ab, 18Bb of the antenna patterns 18A, 18B are electrically connected to coupling electrodes of the RFIC module 14 although details will be described later. Each of the coupling portions 18Ab, 18Bb is a rectangular land.

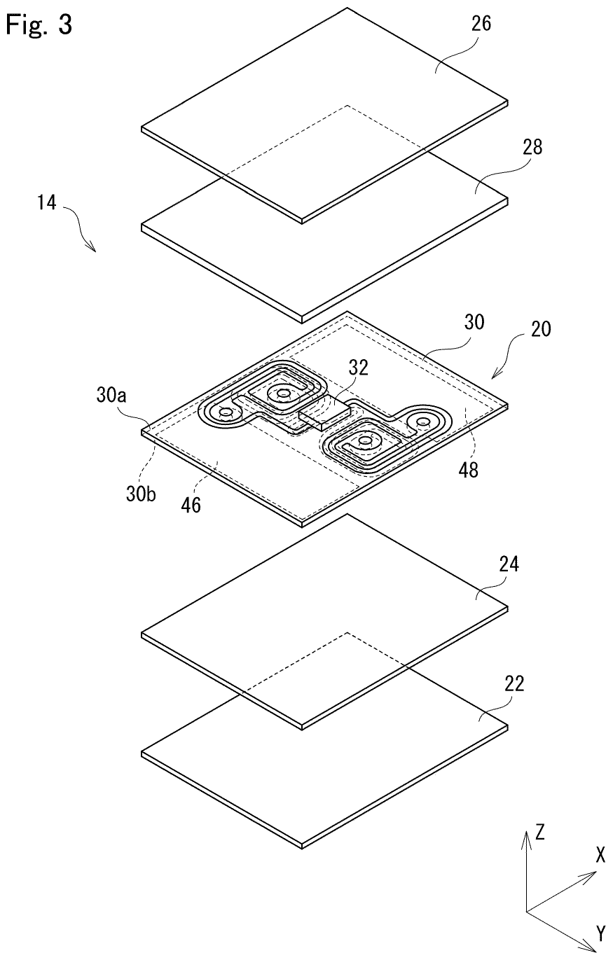

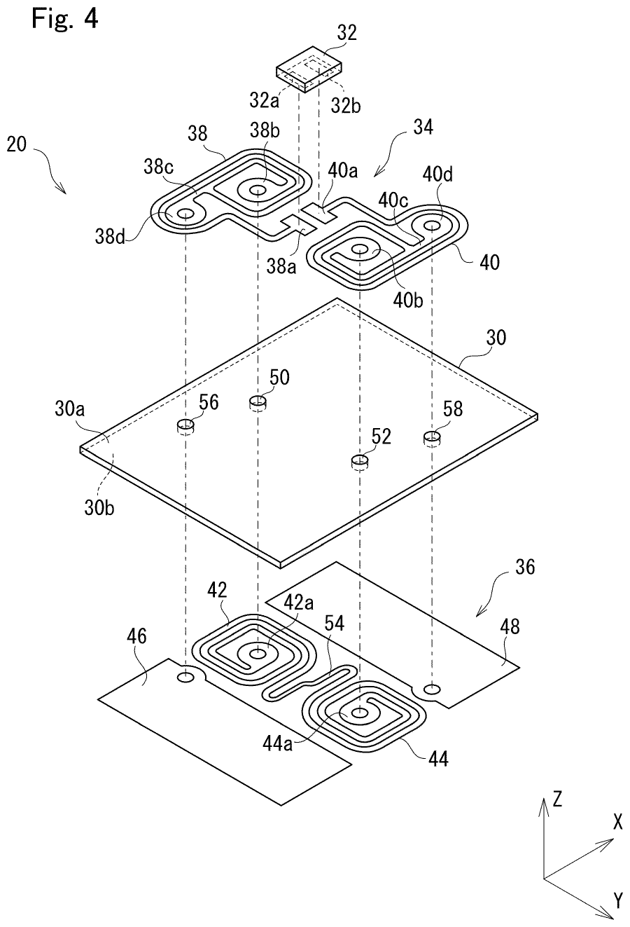

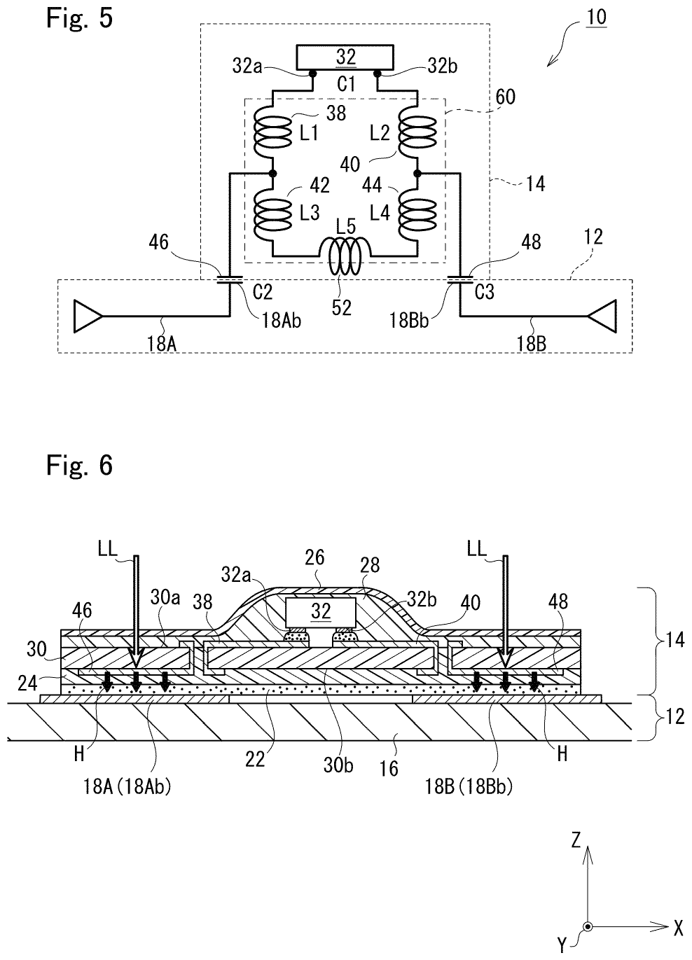

FIG. 3 is an exploded perspective view of the RFIC module. FIG. 4 is an exploded perspective view of an electronic component in the RFIC module. Further, FIG. 5 is an equivalent circuit diagram of the wireless communication device.

As shown in FIGS. 3 and 4, the RFIC module 14 is a device that is configured to perform wireless communication via the antenna patterns 18A, 18B at a communication frequency of, for example, a 900 MHz band, that is, a UHF band.

As shown in FIG. 3, in the case of the present exemplary embodiment, the RFIC module 14 is an electronic component module having a multilayer structure including an electronic component 20. Specifically, the RFIC module 14 includes the electronic component 20 and a hot melt adhesive layer 22 for sticking the electronic component 20 to the antenna member 12. Further, in the case of the present exemplary embodiment, the RFIC module 14 includes a bottom sheet 24 (also referred to as a second substrate) interposed between the electronic component 20 and the hot melt adhesive layer 22, a top sheet 26, and an adhesive sheet 28 for bonding the top sheet 26 to the electronic component 20.

As shown in FIG. 4, the electronic component 20 in the RFIC module 14 includes a base sheet 30 (also referred to as a first substrate), an RFIC chip 32 mounted on one surface 30a of the base sheet 30, a conductor pattern 34 formed on the one surface 30a of the base sheet 30, and a conductor pattern 36 formed on another surface 30b (a first surface) of the base sheet 30 opposite to the one surface 30a.

The base sheet 30 in the electronic component 20 of the RFIC module 14 is a thin plate-like insulating sheet, and can be made of an insulating material, such as polyimide or liquid crystal polymer, for example.

The RFIC chip 32 is an IC chip that drives at a frequency (e.g., a communication frequency) in the UHF band, and has a structure in which various elements are incorporated in a semiconductor substrate made of a semiconductor such as silicon. In addition, the RFIC chip 32 includes a first input/output terminal 32a and a second input/output terminal 32b. Further, as shown in FIG. 5, the RFIC chip 32 includes an internal capacitance (a capacitance: a self-capacitance of the RFIC chip itself) C1.

In the exemplary aspect, the conductor pattern 34 can be a pattern made of a conductor material such as silver, copper, or aluminum. As further shown, the conductor pattern 34 includes two spiral coil portions 38, 40.

At an outer peripheral side end of the coil portion 38 in the conductor pattern 34, a land portion 38a electrically connected to the first input/output terminal 32a of the RFIC chip 32 via, for example, solder (not shown) is provided. In addition, a land portion 38b for electrically connecting to the conductor pattern 36 is provided at a center side end of the coil portion 38. In addition, a land portion 38d for electrically connecting to the conductor pattern 36 is also provided at a tip of a branch portion 38c branched from a portion of the coil portion 38 between the outer peripheral side end (the land portion 38a) and the central side end (the land portion 38b).

In addition, as shown in FIG. 5, the coil portion 38 functions as an inductance element having an inductance L1.

At an outer peripheral side end of the coil portion 40 in the conductor pattern 34, a land portion 40a electrically connected to the second input/output terminal 32b of the RFIC chip 32 via, for example, solder (not shown) is provided. In addition, a land portion 40b for electrically connecting to the conductor pattern 36 is provided at a center side end of the coil portion 40. In addition, a land portion 40d for electrically connecting to the conductor pattern 36 is also provided at a tip of a branch portion 40c branched from a portion of the coil portion 40 between the outer peripheral side end (the land portion 40a) and the center side end (the land portion 40b).

In addition, as shown in FIG. 5, the coil portion 40 is configured to function as an inductance element having an inductance L2.

The conductor pattern 36 can be a pattern made of a conductor material, such as silver, copper, or aluminum. The conductor pattern 36 includes two spiral coil portions 42, 44 and two coupling electrodes 46, 48.

A land portion 42a is provided at a center side end of the coil portion 42 in the conductor pattern 36. The land portion 42a is electrically connected to the land portion 38b of the coil portion 38 in the conductor pattern 34 via an interlayer connection conductor 50 such as a through-hole conductor penetrating the base sheet 30.

In addition, as shown in FIG. 5, the coil portion 42 is configured to function as an inductance element having an inductance L3.

A land portion 44a is provided at a center side end of the coil portion 44 in the conductor pattern 36. The land portion 44a is electrically connected to the land portion 40b of the coil portion 40 in the conductor pattern 34 via an interlayer connection conductor 52 such as a through-hole conductor penetrating the base sheet 30.

In addition, as shown in FIG. 5, the coil portion 44 is configured to function as an inductance element having an inductance L4.

Each of outer peripheral side ends of the two coil portions 42, 44 are electrically connected via a connection portion 54. The connection portion 54 is configured to function as an inductance element having an inductance L5.

The coupling electrodes 46, 48 in the conductor pattern 36 are electrodes for capacitive-coupling with the coupling portions 18Ab, 18Bb of the antenna patterns 18A, 18B of the antenna member 12. In the case of the present exemplary embodiment, the coupling electrodes 46, 48 each have a rectangular shape and are disposed at an interval. The coil portions 42, 44 and the connection portion 54 are disposed between the coupling electrodes 46, 48.

The coupling electrode 46 is electrically connected to the land portion 38d of the coil portion 38 in the conductor pattern 34 via an interlayer connection conductor 56, such as a through-hole conductor penetrating the base sheet 30. The coupling electrode 48 is electrically connected to the land portion 40d of the coil portion 40 via an interlayer connection conductor 58.

As shown in FIG. 5, a matching circuit 60 is configured of the coil portions 38, 40 in the conductor pattern 34, the coil portions 42, 44 and the connection portion 54 in the conductor pattern 36, and a self-capacitance C1 of the RFIC chip 32. By this matching circuit 60, impedances between the RFIC chip 32 and the coupling electrodes 46, 48 are matched at a predetermined frequency (the communication frequency) according to the exemplary aspect.

Returning to FIG. 3, the hot melt adhesive layer 22 is provided on the other surface 30b (that is, the surface on a side of the antenna member 12) of the base sheet 30 in the electronic component 20 of the RFIC module 14. Specifically, in the case of the present exemplary embodiment, the hot melt adhesive layer 22 is provided on the other surface 30b of the base sheet 30 in a state where the bottom sheet 24 (the second substrate) is interposed between the other surface 30b of the base sheet 30 and the hot melt adhesive layer 22. In addition, the hot melt adhesive layer 22 is provided on the base sheet 30 so as to cover the coupling electrodes 46, 48.

A hot melt adhesive including the hot melt adhesive layer 22 is softened (e.g., partially melted) when heated from a cured state, and is cured again when cooled in a softened state. In the case of the present exemplary embodiment, the hot melt adhesive is, for example, an EVA-based thermoplastic resin that maintains the cured state and is not deformed at a temperature of a use environment of the wireless communication device 10. In addition, in the case of the present exemplary embodiment, the hot melt adhesive layer 22 in the cured state has insulating properties. Further, in the present exemplary embodiment, the hot melt adhesive layer 22 has a lower melting temperature than the other components of the RFIC module 14, such as the base sheet 30, for example, a melting temperature of 70 to 200 degrees. When bonded, the hot melt adhesive layer 22 is heated, for example, at about 95 degrees to be softened.

FIG. 6 is a cross-sectional view of a part of the wireless communication device including the RFIC module immediately before sticking.

As shown in FIG. 6, the hot melt adhesive layer 22 is interposed between the RFIC module 14 and the antenna member 12, and bonds them to each other. Specifically, the RFIC module 14 is bonded to the antenna member 12 in a state where the coupling electrode 46 and the coupling portion 18Ab of the antenna pattern 18A face each other, and the coupling electrode 48 and the coupling portion 18Bb of the antenna pattern 18B face each other. Therefore, the coupling electrode 46 and the coupling portion 18Ab are capacitive-coupled with the hot melt adhesive layer 22 and the bottom sheet 24 interposed therebetween (a capacitance C2 is formed as shown in FIG. 5). In addition, the coupling electrode 48 and the coupling portion 18Bb are capacitive-coupled with the hot melt adhesive layer 22 and the bottom sheet 24 interposed therebetween (a capacitance C3 is formed).

The bottom sheet 24 (i.e., the second substrate) interposed between the base sheet 30 and the hot melt adhesive layer 22 can be made of, for example, an insulating material such as an epoxy resin. In addition, the bottom sheet 24 is provided on the other surface 30b of the base sheet 30 so as to cover the coupling electrodes 46, 48. The hot melt adhesive layer 22 is provided on a surface of the bottom sheet 24 opposite to a surface facing the base sheet 30. The bottom sheet 24 is, for example, thermocompression-bonded to the base sheet 30.

The bottom sheet 24 protects the conductor pattern 36 including the coupling electrodes 46, 48 on the other surface 30b of the base sheet 30. In addition, the bottom sheet 24 suppresses variations in a distance between the coupling electrode 46 and the coupling portion 18Ab of the antenna pattern 18A and a distance between the coupling electrode 48 and the coupling portion 18Bb of the antenna pattern 18B, that is, variations in capacitance therebetween.

For example, when only the hot melt adhesive layer 22 exists between the coupling electrode 46 and the coupling portion 18Ab, it is difficult to manage a distance therebetween. That is, when the RFIC module 14 is bonded to the antenna member 12, it is necessary to manage a thickness of the hot melt adhesive layer 22 so that the coupling electrode 46 and the coupling portion 18Ab are not short-circuited. On the other hand, when the bottom sheet 24 exists between the coupling electrode 46 and the coupling portion 18Ab, since a thickness of the bottom sheet 24 is constant, the coupling electrode 46 and the coupling portion 18Ab are not short-circuited. As a result, the variations in the distance between the coupling electrode 46 and the coupling portion 18Ab that cause a short circuit can be suppressed.

The top sheet 26 is, for example, a sheet-shaped member made of a resin material such as polyethylene terephthalate (PET), and is provided on the one surface 30a of the base sheet 30. The top sheet 26 is bonded to the base sheet 30 via an adhesive sheet 28 made of an epoxy resin, for example. As a result, the top sheet 26 (and the adhesive sheet 28) is configured to protect the IC chip 32 and the conductor pattern 34 provided on the one surface 30a of the base sheet 30. It is noted that the adhesive sheet 28 is not limited to the thermosetting resin material. In addition to the thermosetting resin material, an adhesive, such as a hot melt agent, may be used according to an exemplary aspect. As a result, an adhesive strength between the top sheet 26 and the base sheet 30 is improved, and when the hot melt agent is softer than the thermosetting resin, a flexibility of the RFIC module is also improved.

According to the above-described wireless communication device 10, when the antenna patterns 18A, 18B receive a radio wave (signal) of the predetermined frequency (e.g., the communication frequency) in the UHF band, a current corresponding to the signal flows from the antenna patterns 18A, 18B to the RFIC chip 32. The RFIC chip 32 is driven by supply of the current, and outputs a current (a signal) corresponding to information stored in a storage unit (not shown) inside the RFIC chip 32 to the antenna patterns 18A, 18B. Then, a radio wave (a signal) corresponding to the current is radiated from the antenna patterns 18A, 18B.

The configuration of the wireless communication device 10 according to the present exemplary embodiment has been described above. Hereinafter, a method for bonding the RFIC module 14 to the antenna member 12 via the hot melt adhesive layer 22 will be described.

As shown in FIG. 6, when the RFIC module 14 is bonded to the antenna member 12, first, the RFIC module 14 is placed on the antenna member 12. For example, the RFIC module 14 is placed on the antenna member 12 by a mounting apparatus (not shown). When the RFIC module 14 is placed on the antenna member 12, the hot melt adhesive layer 22 is in a cured state and has no adhesive ability.

When the RFIC module 14 has been placed on the antenna member 12, the hot melt adhesive layer 22 is heated and softened. In the case of the present exemplary embodiment, a heating apparatus (not shown) that emits laser light LL (white arrow) is used to heat the hot melt adhesive layer 22. The RFIC module 14 is configured so that the hot melt adhesive layer 22 can be heated using the laser light LL.

Specifically, as shown in FIG. 6, the laser light LL has a wavelength of, for example, about 900 nm, and is applied not to the hot melt adhesive layer 22 but to the coupling electrodes 46, 48 covered with the hot melt adhesive layer 22. The coupling electrodes 46, 48 are heated by the laser light LL to be in a high temperature state throughout. Heat H (black arrows) transfers throughout from the coupling electrodes 46, 48 in the high temperature state to the hot melt adhesive layer 22, which results in heating and softening throughout the hot melt adhesive layer 22. That is, the coupling electrodes 46, 48 function as heat spreaders. It is noted that, unlike this, when the hot melt adhesive layer 22 is directly irradiated with the laser light LL, there is a possibility that a portion irradiated with the laser light LL is excessively melted, for example, liquefied before the hot melt adhesive layer 22 is softened throughout.

When the coupling electrodes 46, 48 functioning as heat spreaders are heated using the laser light LL in this manner, the coupling electrodes 46, 48 are made of a material having a high light absorption rate. Therefore, the coupling electrodes 46, 48 are made of copper according to some exemplary aspects. When the coupling electrodes 46, 48 are made of copper, an oxide film (a copper oxide layer) having a high light absorption rate is formed on each of the surfaces thereof. As a result, the laser light LL is absorbed by the coupling electrodes 46, 48 without being reflected.

In order to efficiently performing the above-described heating of the hot melt adhesive layer 22 via the coupling electrodes 46, 48, a thermal resistance between the coupling electrodes 46, 48 and the hot melt adhesive layer 22 is made smaller than a thermal resistance between the coupling electrodes 46, 48 and the base sheet 30. For purposes of this disclosure, it is noted that the term “thermal resistance” as used herein refers to a numerical value of difficulty in heat transfer, and the larger the value is, the more difficult the heat transfer is.

It is also noted that in the case of the present exemplary embodiment, the bottom sheet 24 is interposed between the coupling electrodes 46, 48 and the hot melt adhesive layer 22. Therefore, a thermal resistance between the coupling electrodes 46, 48 and the bottom sheet 24 is made smaller than the thermal resistance between the coupling electrodes 46, 48 and the base sheet 30.

Due to this difference in thermal resistance, most of the heat generated in the coupling electrodes 46, 48 heated by the laser light LL moves to the hot melt adhesive layer 22 via the bottom sheet 24. As a result, the hot melt adhesive layer 22 can be efficiently softened in a short time.

In order to make the thermal resistance between the coupling electrodes 46, 48 and the bottom sheet 24 smaller than the thermal resistance between the coupling electrodes 46, 48 and the base sheet 30, in the present exemplary embodiment, conductive particles such as carbon particles and aluminum particles are dispersed into the bottom sheet 24.

In the present exemplary embodiment, the base sheet 30 can be made of polyimide, and the bottom sheet 24 can be made of an epoxy resin. The former has a thermal conductivity of 0.28 to 0.34 [W/m·K], and the latter has a thermal conductivity of 0.3 [W/m·K]. Accordingly, the thermal conductivities of materials of the base sheet 30 and the bottom sheet 24 themselves are substantially the same. That is, the thermal resistance between the coupling electrodes 46, 48 and the base sheet 30 and the thermal resistance between the coupling electrodes 46, 48 and the bottom sheet 24 are substantially the same. Therefore, in the case of the present exemplary embodiment, the conductive particles are dispersed into the bottom sheet 24.

When the conductive particles having a high thermal conductivity are dispersed into the bottom sheet 24, heat is easily transferred from the coupling electrodes 46, 48 into the bottom sheet 24. On the other hand, the conductive particles are not dispersed in the base sheet 30. As a result, even if the thermal conductivities of the materials of the bottom sheet 24 and the base sheet 30 are substantially the same, the thermal resistance between the coupling electrodes 46, 48 and the bottom sheet 24 can be made smaller than the thermal resistance between the coupling electrodes 46, 48 and the base sheet. Therefore, most of the heat H generated in the coupling electrodes 46, 48 can move to the bottom sheet 24 instead of the base sheet 30.

In addition to or in instead of dispersing the conductive particles into the bottom sheet 24, the bottom sheet 24 may be made of a material having a higher thermal conductivity than the thermal conductivity of the material of the base sheet 30 according to an exemplary aspect. This configuration also makes the thermal resistance between the coupling electrodes 46, 48 and the bottom sheet 24 smaller than the thermal resistance between the coupling electrodes 46, 48 and the base sheet 30.

In addition, in the case of the present exemplary embodiment, as shown in FIG. 6, the laser light LL passes through the top sheet 26, the adhesive sheet 28, and the base sheet 30 and reaches the coupling electrodes 46, 48. Therefore, the top sheet 26, the adhesive sheet 28, and the base sheet 30 are each made of a light transmissive material. In particular, according to an exemplary aspect, the base sheet 30 is made of a material having a light absorption rate lower than light absorption rates of the coupling electrodes 46, 48. As a result, the laser light LL having a higher light amount can reach the coupling electrodes 46, 48.

Further, in the case of the present exemplary embodiment, as shown in FIGS. 2 and 3, the RFIC chip 32 is provided on the one surface 30a of the base sheet 30. In addition, the RFIC chip 32 is provided on the one surface 30a so as not to overlap the coupling electrodes 46, 48 in plan view (as viewed in the Z-axis direction) of the base sheet 30. Specifically, in the case of the present exemplary embodiment, the coupling electrodes 46, 48 are arranged at an interval in the longitudinal direction (X-axis direction). The RFIC chip 32 is located between the coupling electrodes 46, 48. As a result, the laser light LL is prevented from hitting the RFIC chip 32, and the laser light LL can reach the coupling electrodes 46, 48 without being disturbed by the RFIC chip 32.

As described above, according to the present exemplary embodiment, the RFIC module 14 can be stuck to the antenna member 12 including the antenna patterns 18A, 18B via the hot melt adhesive layer 22 in a short time.

It is noted that although the present disclosure has been described with reference to the above-described exemplary embodiment, embodiments of the present disclosure are not limited thereto.

For example, in the case of the above-described exemplary embodiment, as shown in FIG. 3, in the RFIC module 14, the insulating bottom sheet 24 is interposed between the electronic component 20 and the hot melt adhesive layer 22. However, embodiments of the present disclosure are not limited thereto.

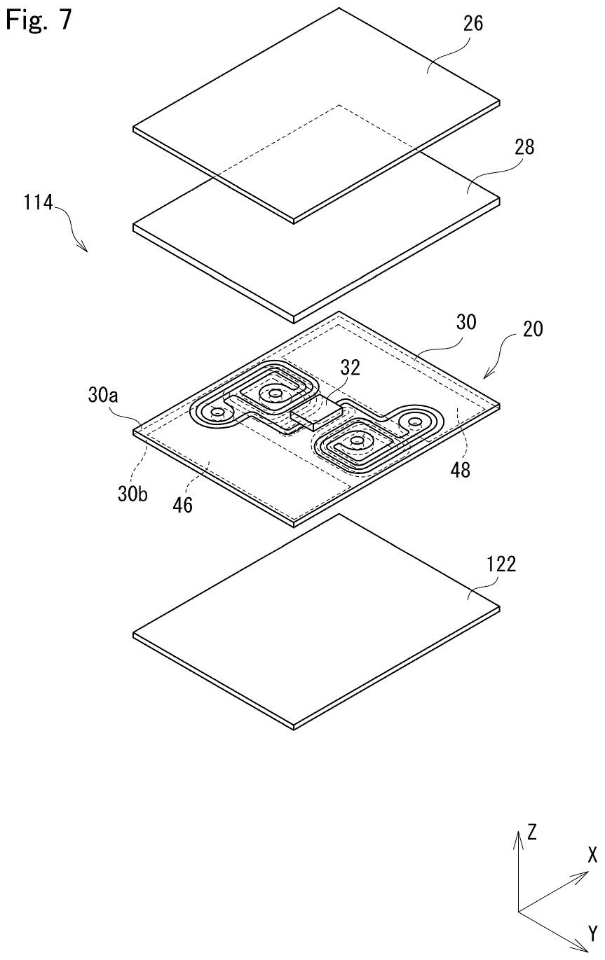

FIG. 7 is an exploded perspective view of an RFIC module according to another exemplary embodiment of the present disclosure.

As shown in FIG. 7, in the RFIC module 114 according to another exemplary embodiment, a hot melt adhesive layer 122 is directly provided on the electronic component 20 and covers the coupling electrodes 46, 48, similarly to the bottom sheet 24 of the above-described exemplary embodiment. In this case, a thermal resistance between the coupling electrodes 46, 48 and the hot melt adhesive layer 122 is made smaller than the thermal resistance between the coupling electrodes 46, 48 and the base sheet 30.

In addition, in the case of the above-described exemplary embodiment, as shown in FIG. 3, the hot melt adhesive layer 22 for bonding the RFIC module 14 and the antenna member 12 is provided in the RFIC module 14. However, embodiments of the present disclosure are not limited thereto. The hot melt adhesive layer 22 is provided on the antenna member 12 according to an exemplary aspect.

Furthermore, in the case of the above-described exemplary embodiment, as shown in FIG. 6, the coupling electrodes 46, 48 are heated by irradiation with the laser light LL. This is because the coupling electrodes 46, 48 are not exposed to an outside. However, embodiments of the present disclosure are not limited thereto, and for example, a part of the coupling electrodes 46, 48 may be exposed, and a heat transfer member may be brought into contact with the exposed portion with the heat transfer member heated according to an exemplary aspect.

Furthermore, in the case of the above-described exemplary embodiment, in the wireless communication device 10, the coupling electrodes 46, 48 of the electronic component 20 in the RFIC module 14 are capacitive-coupled to the coupling portions 18Ab, 18Bb of the antenna patterns 18A, 18B of the antenna member 12. Therefore, as shown in FIGS. 2 and 6, the coupling electrodes 46, 48 face the coupling portions 18Ab, 18Bb at intervals in the thickness direction (Z-axis direction) of the wireless communication device 10. That is, they are electric-field-coupled. However, embodiments of the present disclosure are not limited thereto.

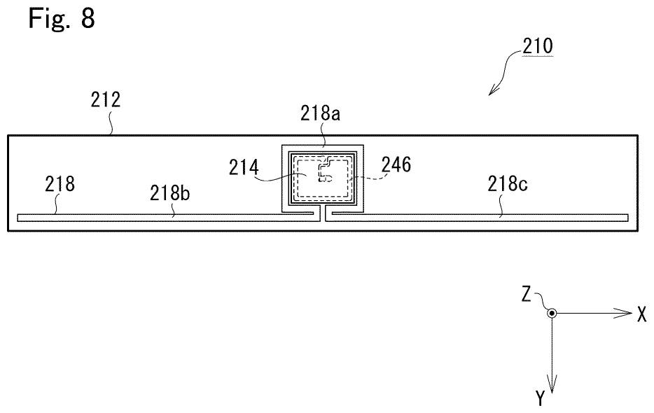

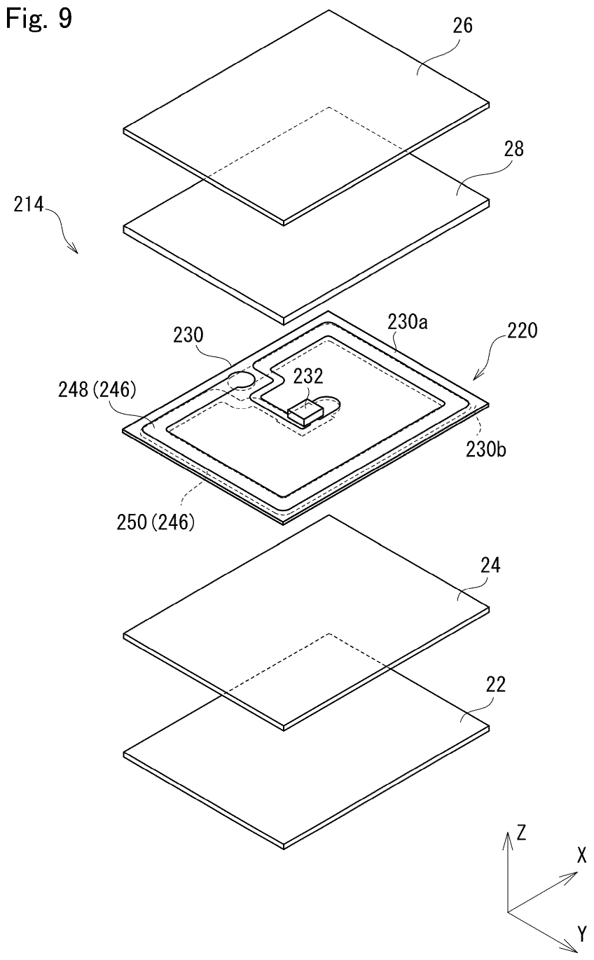

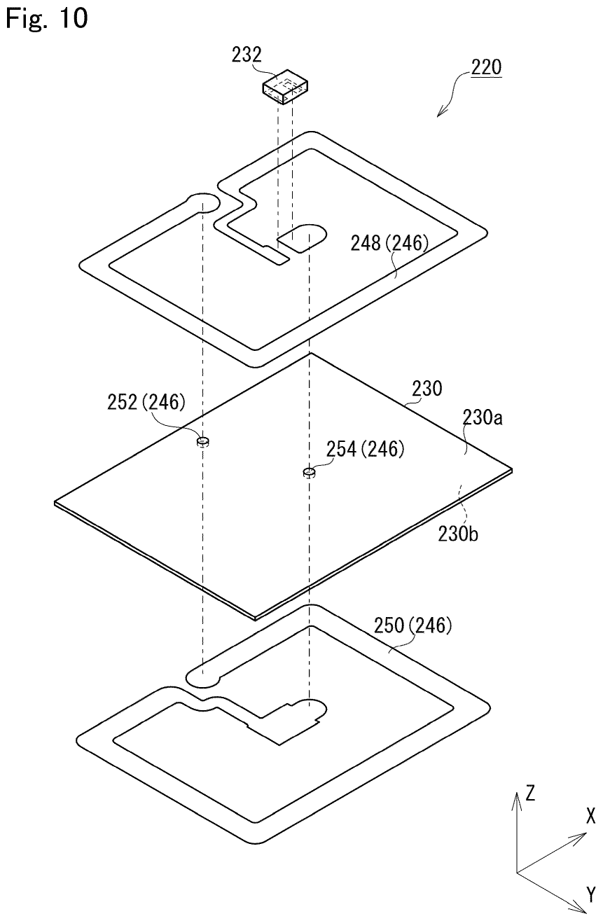

FIG. 8 is a top view of a wireless communication device according to a different exemplary embodiment of the present disclosure. FIG. 9 is an exploded perspective view of an RFIC module in the wireless communication device according to the different exemplary embodiment. FIG. 10 is an exploded perspective view of an electronic component in the RFIC module of the wireless communication device according to the different exemplary embodiment.

As shown in FIG. 8, in a wireless communication device 210 according to the different exemplary embodiment, an antenna member 212 includes an antenna pattern 218 that is magnetic-field-coupled to an RFIC module 214. According to an exemplary aspect, the antenna pattern 218 includes a substantially “C”-shaped coupling portion 218a provided to surround the RFIC module 214, and linear radiating portions 218b, 218c extending in opposite directions from both ends of the coupling portion 218a as viewed in a thickness direction (the Z-axis direction) of the wireless communication device 210.

As shown in FIG. 9, the RFIC module 214 includes an electronic component 220, the bottom sheet 24 interposed between the electronic component 220 and the hot melt adhesive layer 22, the top sheet 26, and the adhesive sheet 28 for bonding the top sheet 26 to the electronic component 220. It is also noted that the bottom sheet 24 may be omitted according to an exemplary aspect.

As shown in FIG. 10, the electronic component 220 includes a base sheet 230, an RFIC chip 232 provided on the base sheet 230, and coil conductors 246 (coupling electrodes) provided on the base sheet 230 and electrically connected to the RFIC chip 232. The coil conductors 246 include a spiral conductor pattern 248 provided on one surface 230a of the base sheet 230, a spiral conductor pattern 250 provided on another surface 230b, and interlayer connection conductors 252, 254, such as through-hole conductors penetrating the base sheet 230 and electrically connecting the conductor patterns 248, 250. The coil conductors 246 are provided on the base sheet 230 so as to surround the RFIC chip 232 as viewed in the thickness direction (Z-axis direction) of the wireless communication device 210.

According to the above-described the wireless communication device 210, when the antenna pattern 218 receives a radio wave, a current flows through the coupling portion 218a of the antenna pattern 218, whereby the coupling portion 218a generates a magnetic field. Due to the magnetic field, a current flows through the coil conductors 246 of the electronic component 220 of the RFIC module 214. The RFIC chip 232 is driven by the supply of the current, and outputs a current corresponding to information stored in a storage unit (not shown) inside the RFIC chip 232 to the coil conductors 246. The coil conductors 246 generates the magnetic field corresponding to the output current, and the current flows through the coupling portion 218a of the antenna pattern 218 by the magnetic field. As a result, the antenna pattern 218 is configured to emit a radio wave corresponding to the current.

Further, according to the above-described RFIC module 214, the coil conductors 246 are heated by irradiation with laser light. The hot melt adhesive layer 22 is heated and softened by the coil conductors 246, and as a result, the RFIC module 214 is bonded to the antenna member 212 via the hot melt adhesive layer 22.

It is noted that such an antenna pattern that can be magnetic-field-coupled to the RFIC module 214 has various forms.

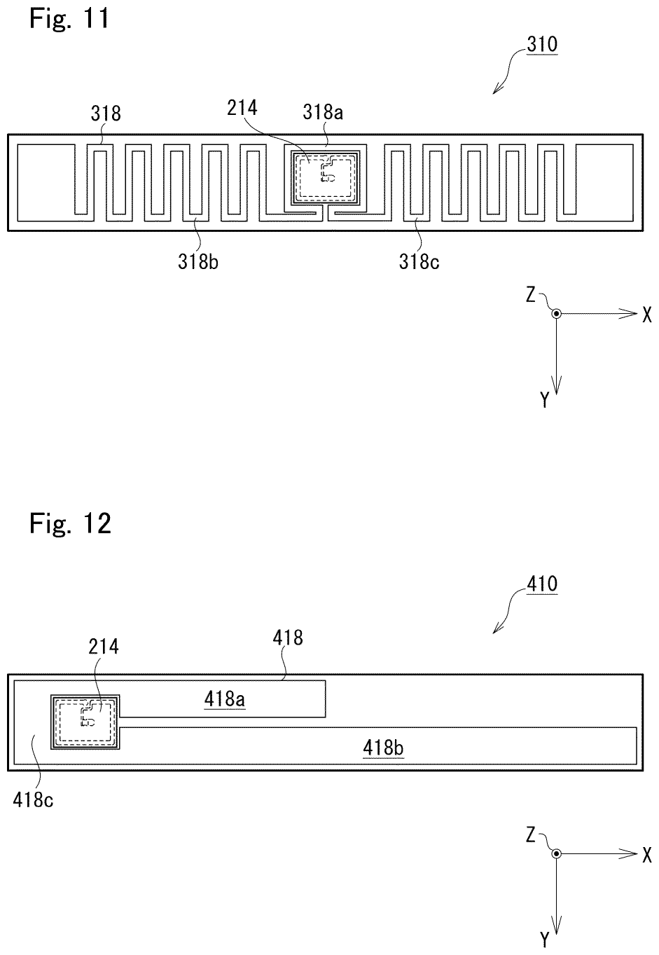

FIGS. 11 and 12 are top views of wireless communication devices according to modifications of the different exemplary embodiment.

For example, as shown in FIG. 11, in a wireless communication device 310 of one modification, an antenna pattern 318 includes a coupling portion 318a having a substantially “C” shape provided to surround the RFIC module 214, and radiating portions 318b, 318c having a meander shape extending in opposite directions from both ends of the coupling portion 318a.

Furthermore, for example, as shown in FIG. 12, in a wireless communication device 410 of another modification, an antenna pattern 418 includes linear radiating portions 418a, 418b extending in parallel at intervals, and a joining portion 418c joining one ends thereof. The RFIC module 214 is surrounded by the two radiating portions 418a, 418b and the joining portion 418c. As a result, the RFIC module 214 is magnetic-field-coupled to the antenna pattern 418.

In addition, in the case of the above-described exemplary embodiment, the electronic component module and the member bonded via the hot melt adhesive layer 22 are the RFIC module 14 and the antenna member 12 in the wireless communication device, but embodiments of the present disclosure are not limited thereto. That is, various aspects of the present disclosure are as follows.

A first exemplary aspect is an electronic component module stuck to a member including a conductor pattern via a hot melt adhesive, the electronic component module has a first substrate, a coupling electrode provided on a first surface of the first substrate on a side of the member and electromagnetically coupled to the conductor pattern, and a second substrate provided on the first surface of the first substrate so as to cover the coupling electrode, wherein a thermal resistance between the coupling electrode and the second substrate is smaller than a thermal resistance between the coupling electrode and the first substrate.

A exemplary second aspect is the electronic component module according to the first aspect having a layer of the hot melt adhesive provided on a surface of the second substrate opposite to a surface facing the first substrate.

A exemplary third aspect is the electronic component module according to the first or second aspect that conductive particles are dispersed into the second substrate.

A exemplary fourth aspect is the electronic component module according to any one of the first to third aspects that the second substrate is made of a material having a higher thermal conductivity than a thermal conductivity of a material of the first substrate.

A exemplary fifth aspect is the electronic component module according to the first aspect that the second substrate is a layer of the hot melt adhesive.

A exemplary sixth aspect is the electronic component module according to any one of the first to fifth aspects that the first substrate is made of a material having a light absorption rate lower than a light absorption rate of the coupling electrode.

A exemplary seventh aspect is the electronic component module according to any one of the first to sixth aspects having an IC chip provided on a second surface of the first substrate opposite to the first surface and electrically connected to the coupling electrode, and the IC chip is provided on the second surface so as not to overlap the coupling electrode in plan view of the first substrate.

An exemplary eighth aspect is a wireless communication device having the electronic component module according to any one of the first to seventh aspects, and an antenna member including an antenna pattern electromagnetically coupled to the coupling electrode of the electronic component module, the electronic component module stuck thereto via a hot melt adhesive.

The exemplary embodiment of the present disclosure are applicable to sticking an electronic component module including a coupling electrode and a member including a conductor pattern capacitive-coupled or magnetic-field-coupled to the coupling electrode via a hot melt adhesive.

What is claimed is:

1. An electronic component module, comprising:
a first substrate;
a coupling electrode on a first surface of the first substrate, the coupling electrode being configured to be electromagnetically coupled with a conductor pattern on an antenna member; and
a second substrate on the first surface of the first substrate, the second substrate covering the coupling electrode,
wherein a first thermal resistance between the coupling electrode and the second substrate is smaller than a second thermal resistance between the coupling electrode and the first substrate.

2. The electronic component module according to claim 1, further comprising a layer of a hot melt adhesive on a surface of the second substrate that is opposite to a surface of the second substrate that faces the first substrate.

3. The electronic component module according to claim 1, wherein conductive particles are dispersed into the second substrate.

4. The electronic component module according to claim 1, wherein the second substrate comprises a second material having a thermal conductivity that is higher than a thermal conductivity of a first material of the first substrate.

5. The electronic component module according to claim 1, wherein the second substrate is a layer of a hot melt adhesive.

6. The electronic component module according to claim 1, wherein the first substrate comprises a material having a first light absorption rate that is lower than a second light absorption rate of the coupling electrode.

7. The electronic component module according to claim 1, further comprising:
an integrated circuit (IC) chip on a second surface of the first substrate opposite to the first surface and being electrically connected to the coupling electrode,
wherein the IC chip is on the second surface without overlapping the coupling electrode in a plan view of the first substrate.

8. A wireless communication device, comprising:
an antenna member including an antenna pattern; and
an electronic component module having a first substrate, a second substrate and a coupling electrode between the first substrate and the second substrate, wherein:
a first thermal resistance between the coupling electrode and the second substrate is smaller than a second thermal resistance between the coupling electrode and the first substrate;
the second substrate is stuck to the antenna member via a hot melt adhesive; and
the coupling electrode is electromagnetically coupled with the antenna pattern of the antenna member.

9. The wireless communication device according to claim 8, wherein the electronic component module comprises a layer of the hot melt adhesive that is on a surface of the second substrate that is opposite to a surface of the second substrate that faces the first substrate.

10. The wireless communication device according to claim 8, wherein conductive particles are dispersed into the second substrate.

11. The wireless communication device according to claim 8, wherein the second substrate comprises a second material having a thermal conductivity that is higher than a thermal conductivity of a first material of the first substrate.

12. The wireless communication device according to claim 8, wherein the second substrate is a layer of the hot melt adhesive.

13. The wireless communication device according to claim 8, wherein the first substrate comprises a material having a first light absorption rate that is lower than a second light absorption rate of the coupling electrode.

14. The wireless communication device according to claim 8, wherein the electronic component module further comprises an integrated circuit (IC) chip on an opposite surface of the first substrate from the coupling electrode without overlapping the coupling electrode in a plan view of the first substrate, the IC being electrically connected to the coupling electrode.

15. An electronic component module, comprising:
a first substrate;
a second substrate; and
at least a coupling electrode between the first substrate and the second substrate,
wherein the second substrate is configured to be stuck to an antenna member via a hot melt adhesive, and cause the coupling electrode to be electromagnetically coupled with an antenna pattern of the antenna member, and
wherein a first thermal resistance between the coupling electrode and the second substrate is smaller than a second thermal resistance between the coupling electrode and the first substrate.

16. The electronic component module according to claim 15, wherein the electronic component module comprises a layer of the hot melt adhesive that is on a surface of the second substrate that is opposite to a surface of the second substrate that faces the first substrate.

17. The electronic component module according to claim 15, wherein conductive particles are dispersed into the second substrate.

18. The electronic component module according to claim 15, wherein the second substrate comprises a second material having a higher thermal conductivity than a thermal conductivity of a first material of the first substrate.

19. The electronic component module according to claim 15, wherein the second substrate is a layer of the hot melt adhesive.

20. The electronic component module according to claim 15, wherein the first substrate comprises a material having a first light absorption rate that is lower than a second light absorption rate of the coupling electrode.
